(19) United States
(12) Patent Application Publication
(10) Pub. No.: US 2026/0301776 A1
(43) Pub. Date: Oct. 1, 2026

(54) MEMORY DEVICE

(71) Applicant: SK hynix Inc., Icheon-si (KR)

(72) Inventor: Heon Yong CHANG, Icheon-si (KR)

(21) Appl. No.: 19/289,681

(22) Filed: Aug. 4, 2025

(30) Foreign Application Priority Data
Mar. 31, 2025 (KR) 10-2025-0041232

(51) Int. Cl. G11C 5/06; H10B 12/00; H10D 64/68

(52) U.S. Cl. CPC G11C 5/063; H10B 12/50; H10D 64/693

(57) ABSTRACT

A memory device may include a substrate including a cell region and a peripheral region, a conductive layer disposed over the substrate, and located in the peripheral region, a first capping insulating layer over the conductive layer, a contact plug contacting an upper surface of the conductive layer, and a wiring layer contacting an upper surface of the contact plug. A distance from the upper surface of the contact plug to the conductive layer is less than a distance from an upper surface of the first capping insulating layer to the conductive layer.

### CROSS-REFERENCE TO RELATED APPLICATION

The present application claims priority under 35 U.S.C. §119(a) to Korean Patent Application No. 10-2025-0041232 filed on March 31, 2025, which is incorporated herein by reference in its entirety.

### BACKGROUND

### 1. Technical Field

Embodiments of the present disclosure relate to a memory device.

### 2. Related Art

Memory devices are attracting attention in the electronics industry due to their characteristics such as miniaturization, multifunctionality and/or low manufacturing cost. As the electronics industry advances, memory devices are becoming increasingly highly integrated, and the difficulty of forming various wirings and elements included in memory devices is increasing. For example, as the distance between wirings included in a memory device decreases, the probability of occurrence of interference or a short circuit between wirings increases.

### SUMMARY

Objects of embodiments of the disclosure are not limited to those set forth herein, and other objects may be apparent to one of ordinary skill in the art in light of the following description.

Embodiments of the present disclosure are directed to providing a memory device capable of minimizing a process defect by substantially preventing a short circuit between neighboring wirings.

In an embodiment, a memory device may include a substrate including a cell region and a peripheral region, a conductive layer disposed over the substrate, and located in the peripheral region, a first capping insulating layer over the conductive layer, a contact plug contacting the upper surface of the conductive layer, and having the distance from the upper surface thereof to the conductive layer less than the distance from the upper surface of the first capping insulating layer to the conductive layer, and a wiring layer contacting the upper surface of the contact plug.

In an embodiment, a memory device may include: a substrate including a cell region and a peripheral region, a conductive layer disposed over the substrate, and located in the peripheral region, a contact plug contacting the upper surface of the conductive layer, and a wiring layer including a first wiring section and a second wiring section, the first wiring section contacting an upper surface of the contact plug and including a lower surface that has substantially the same width as the upper surface of the contact plug, the second wiring section being integrally formed with the first wiring section and including a lower surface that has a width larger than the upper surface of the first wiring section.

In an embodiment, a memory device may include a substrate, a conductive layer over the substrate, a first insulating layer on the conductive layer, a first capping insulating layer on the first insulating layer, a contact plug contacting the upper surface of the conductive layer, passing through the first insulating layer, and including an upper surface that is located between the upper surface of the first capping insulating layer and the upper surface of the first insulating layer, and a wiring layer including a first wiring section and a second wiring section, the first wiring section contacting the upper surface of the contact plug and including a lower surface having substantially the same width as the upper surface of the contact plug, the second wiring section being integrally formed with the first wiring section and including a lower surface that has a width larger than the upper surface of the first wiring section.

According to embodiments of the present disclosure, it is possible to provide a memory device capable of minimizing a process defect by preventing a short circuit between neighboring wirings.

The effects of the disclosure are not limited to the foregoing effects, and other effects may be apparent to one of ordinary skill in the art in light of the following detailed description.

### BRIEF DESCRIPTION OF THE DRAWINGS

The disclosure will be more fully understood from the following detailed description and the accompanying drawings, which are provided for illustration only and are not intended to limit the disclosure.

FIG. 1 is a view illustrating a planar structure of a memory device according to embodiments of the present disclosure.

FIG. 2 is a view illustrating a cross-sectional structure of a part indicated by a line I-I' of FIG. 1 according to embodiments of the present disclosure.

FIG. 3 and FIG. 4 are enlarged views of a part 10 of FIG. 2 according to embodiment of the present disclosure.

FIG. 5 is a view illustrating a planar structure of a memory device according to embodiments of the present disclosure.

FIG. 6 is a view illustrating a cross-sectional structure of a part indicated by a line II-II' of FIG. 5 according to embodiments of the present disclosure.

FIG. 7 is an enlarged view of a part 11 of FIG. 6 according to embodiments of the present disclosure.

FIGS. 8, 9, 10, 11, 12, 13, 14 and 15, are views illustrating a method of manufacturing a memory device according to embodiments of the present disclosure.

FIGS. 16 and 17 are views illustrating a method of manufacturing a memory device according to embodiments of the present disclosure. FIG. 18 illustrates a method of manufacturing a memory device according to embodiments of the present disclosure.

### DETAILED DESCRIPTION

Hereinafter, some embodiments of the present disclosure will be described in detail with reference to the accompanying drawings. In the following description, the same elements may be designated by the same reference numerals although they are shown in different drawings. Further, in the following description of the present disclosure, a detailed description of known functions and configurations incorporated herein may be omitted for the interest of brevity. It is to be noticed that the terms “comprising,” “having,” “including” and so on, used in the description and claims, should not be interpreted as being restricted to the means listed thereafter unless specifically stated otherwise. Where an indefinite or definite article is used when referring to a singular noun, e.g., “a,” “an” and “the,” this may include a plural of that noun unless specifically stated otherwise.

Also, in describing the components of the disclosure, there may be terms used like first, second, A, B, (a), and (b). These are solely for the purpose of differentiating one component from another component but do not limit the substances, order, sequence, or number of the components.

When it is mentioned that a first element "is connected or coupled to," “contacts or overlaps,” etc. a second element, it should be interpreted that not only can the first element “be directly connected or coupled to” or “directly contact or overlap” the second element, but at least one intervening element can also be "interposed" between the first and second elements. Here, another component may be included in at least one of the at least two components which are “connected,” “coupled,” or “linked” with each other. Moreover, a first element “on” a second element indicates that the first element can be “directly on” the second element, or that at least one intervening element can be interposed between the first and second elements.

In descriptions for time flow relationships of components, an operating method or a fabricating method, in the case where pre and post relationships in terms of time or pre and post relationships in terms of flow are described, for example, by “after,” “following,” “next,” or “before,” one or more intervening events may be included unless “immediately” or “directly” is used.

In the case where a numerical value for a component or its corresponding information (e.g., a level, etc.) is mentioned, even though there is no separate explicit description, the numerical value or its corresponding information can be interpreted as including an error range that may be caused by various factors (for example, a process variable, an internal or external shock, noise, etc.).

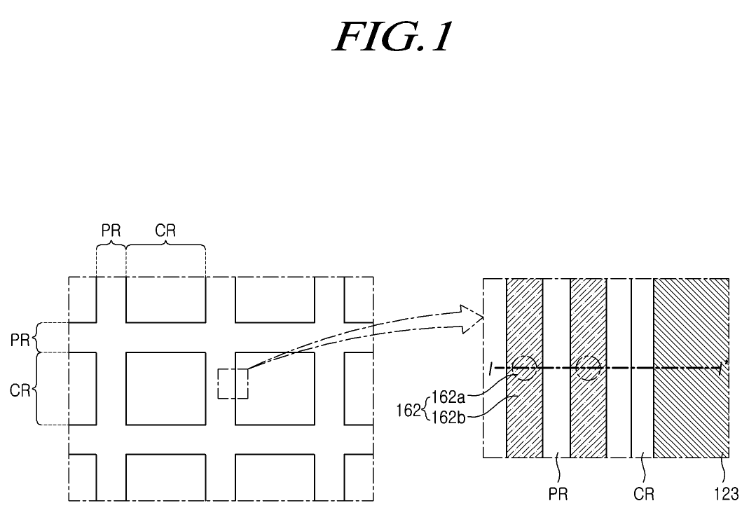

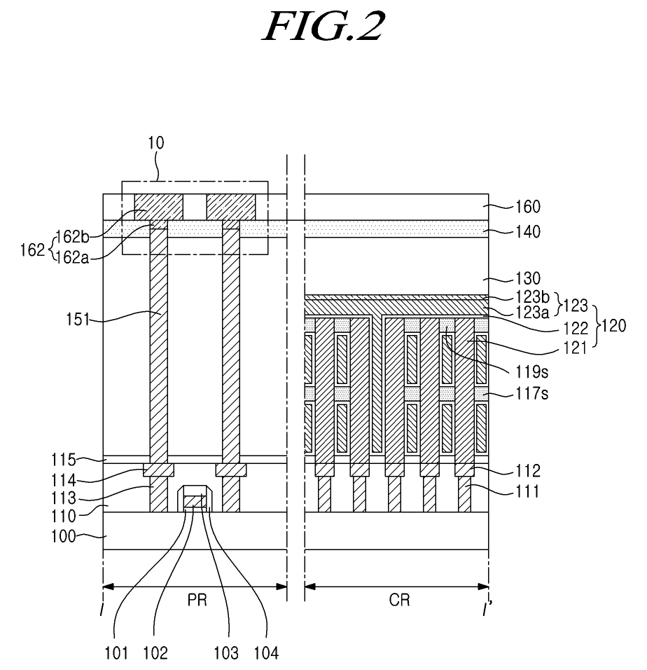

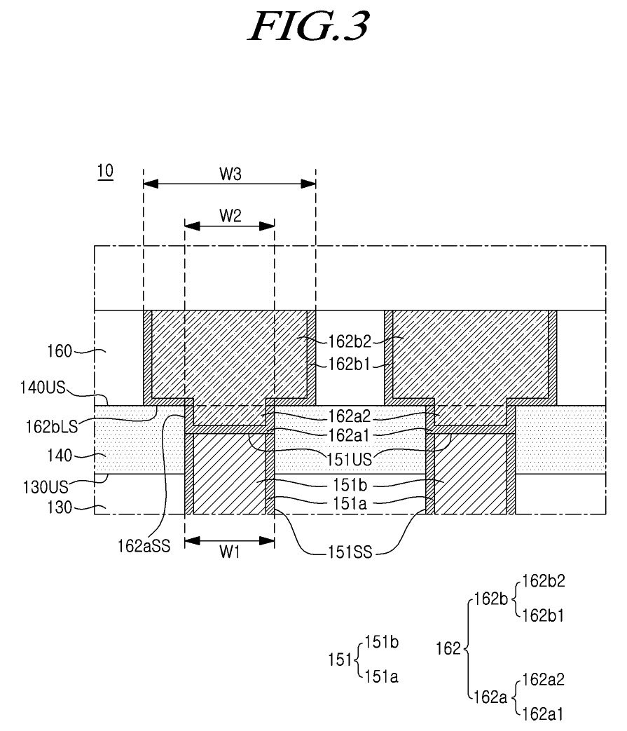

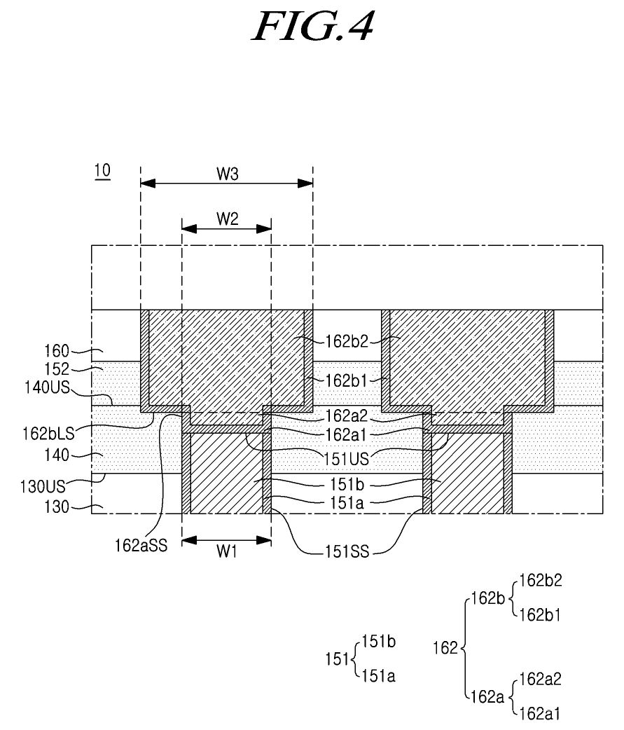

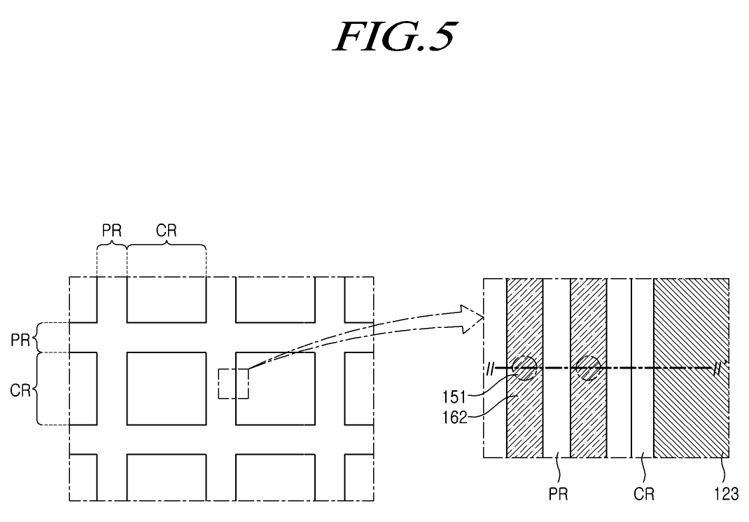

FIG. 1 is a view illustrating a planar structure of a memory device according to embodiments of the present disclosure. FIG. 2 is a view illustrating a cross-sectional structure of a part indicated by a line I-I' of FIG. 1. FIG. 3 and FIG. 4 are enlarged views of a part 10 of FIG. 2 according to embodiments of the present disclosure.

Referring to FIG. 1 to FIG. 3, the memory device may include a substrate 100, a gate insulating layer 101, a gate electrode 102, a gate capping layer 103, a spacer 104, an interlayer insulating layer 110, a storage node contact 111, a landing pad 112, a first contact 113, a conductive layer 114, an etch stop layer 115, a capacitor 120, a first support 117s, a second support 119s, a first insulating layer 130, a first capping insulating layer 140, a contact plug 151, a second insulating layer 160, and a wiring layer 162.

The capacitor 120 includes a lower electrode 121, a dielectric layer 122 and an upper electrode 123. The wiring layer 162 includes a first wiring section 162a and a second wiring section 162b.

The substrate 100 may include a cell region CR and a peripheral region PR. The cell region CR may be a region where memory cells included in the memory device are disposed. The peripheral region PR may be a region where peripheral circuits that transmit various signals and voltages to the memory cells are disposed. The peripheral region PR may be disposed around the cell region CR. In an embodiment, the peripheral region PR may surround the cell region CR.

The substrate 100 may include a semiconductor substrate such as a silicon wafer or a silicon-on-insulator (SOI) wafer. The substrate 100 may include a III-V group semiconductor substrate, for example, a compound semiconductor substrate such as GaAs. The substrate 100 may include monocrystalline silicon, polysilicon, amorphous silicon, monocrystalline silicon germanium, polycrystalline silicon germanium, carbon-doped silicon, or a combination thereof.

The interlayer insulating layer 110 may be disposed on the substrate 100. The interlayer insulation layer 110 in the embodiment shown in FIG. 2 is illustrated as a single layer, but embodiments of the present disclosure are not limited thereto. The interlayer insulating layer 110 may be a multilayer of two or more layers. The interlayer insulating layer 110 may include silicon oxide, silicon nitride, silicon oxynitride, low-k dielectric, high-k dielectric, or a combination thereof.

The storage node contact 111 and the landing pad 112 may be disposed in the interlayer insulation layer 110 in the cell region CR. The storage node contact 111 may penetrate the interlayer insulating layer 110 and contact the upper surface of the substrate 100. The landing pad 112 may contact the storage node contact 111. A bit line (not illustrated) may be additionally disposed in the interlayer insulating layer 110. For example, the bit line may be disposed between storage node contacts 111. A word line (not illustrated) may be additionally disposed in the substrate 100. The storage node contact 111 and the landing pad 112 may include a conductive material such as metal, metal oxide, metal nitride, metal silicide, polysilicon, conductive carbon, or a combination thereof.

The first contact 113 and the conductive layer 114 may be disposed in the interlayer insulating layer 110 in the peripheral region PR. The first contact 113 may penetrate the interlayer insulating layer 110 and contact the upper surface of the substrate 100. The conductive layer 114 may contact the upper surface of the first contact 113. In an embodiment, the first contact 113 may contact a source region (not illustrated) or a drain region (not illustrated) of a transistor that is disposed on the substrate 100. In an embodiment, the conductive layer 114 may be disposed at substantially the same level as the landing pad 112. In an embodiment, the upper surface of the conductive layer 114 may be formed on substantially the same plane as the upper surface of the landing pad 112. The first contact 113 and the conductive layer 114 may include a conductive material such as metal, metal oxide, metal nitride, metal silicide, polysilicon, conductive carbon, or a combination thereof.

The etch stop layer 115 may be disposed on the interlayer insulating layer 110, the landing pad 112, and the conductive layer 114. The etch stop layer 115 may include SiN, SiON, SiCN, SiOCN, or a combination thereof.

The lower electrode 121 may be disposed on the landing pad 112 in the cell region CR. The lower electrode 121 may penetrate the etch stop layer 115 and contact the upper surface of the landing pad 112. The lower electrode 121 may include Ti, Ta, TiN, TaN, TiO, TaO, TiON, TaON, or a combination thereof.

The first support 117s and the second support 119s may be disposed on the side surface of the lower electrode 121. The first support 117s and the second support 119s may surround at least portions of the side surface of the lower electrode 121. The first support 117s and the second support 119s may include SiN, SiON, SiCN, SiOCN, or a combination thereof.

The dielectric layer 122 may be disposed on the lower electrode 121, the first support 117s, and the second support 119s. The dielectric layer 122 may cover the surfaces of the lower electrode 121, the first support 117s, and the second support 119s. The upper electrode 123 may be disposed on the dielectric layer 122. The upper electrode 123 may include a first upper electrode 123a and a second upper electrode 123b on the first upper electrode 123a. The dielectric layer 122 may include silicon oxide, silicon nitride, silicon oxynitride, hafnium oxide (HfO2), zirconium oxide (ZrO2), aluminum oxide (Al2O3), titanium oxide (TiO2), tantalum oxide (Ta2O5), niobium oxide (Nb2O5), strontium titanium oxide (SrTiO3), a ZAZ (ZrO2/Al2O3/ZrO2) stack, a TiO2/ZrO2/Al2O3/ZrO2 stack, a TiO2/HfO2/Al2O3/HfO2 stack, a Ta2O5/ZrO2/Al2O3/ZrO2 stack, a Ta2O5/HfO2/Al2O3/HfO2 stack, or a combination thereof. In an embodiment, the first upper electrode 123a may include Silicon-Germanium (e.g., SiGe) and the second upper electrode 123b may include tungsten nitride (e.g., WN).

The first insulating layer 130 may be disposed on the upper electrode 123 and the etch stop layer 115. The first capping insulating layer 140 may be disposed on the first insulating layer 130. The second insulating layer 160 may be disposed on the first capping insulating layer 140. The first insulating layer 130 may be a single layer or a multilayer of two or more layers. The first insulating layer 130, the first capping insulating layer 140, and the second insulating layer 160 may include silicon oxide, silicon nitride, silicon oxynitride, low-k dielectric, high-k dielectric, or a combination thereof. In an embodiment, the first insulating layer 130 and the second insulating layer 160 may include oxide, and the first capping insulating layer 140 may include nitride.

The contact plug 151 may be disposed on the conductive layer 114 in the peripheral region PR. The contact plug 151 may be connected to the conductive layer 114 by passing through the first capping insulating layer 140, the first insulating layer 130, and the etch stop layer 115. For example, the contact plug 151 may contact the upper surface of the conductive layer 114. Referring to FIG. 1, in an embodiment, the contact plug 151 may be a pillar that has a cross-section with a substantially constant width.

Referring to FIG. 3, the contact plug 151 may include a contact barrier section 151a and a contact conductive section 151b. The contact barrier section 151a may surround the lower surface and side surface of the contact conductive section 151b.

In an embodiment, an upper surface 151US of the contact plug 151 may be located closer to the conductive layer 114 (e.g., an upper surface of the conductive layer 114) than an upper surface 140US of the first capping insulating layer 140. For example, a distance from the upper surface 151US of the contact plug 151 to the conductive layer 114 may be less than a distance from the upper surface 140US of the first capping insulating layer 140 to the conductive layer 114. In an embodiment, the upper surface 151US of the contact plug 151 may be located farther from the conductive layer 114 (e.g., an upper surface of the conductive layer 114) than an upper surface 130US of the first insulating layer 130.

The contact plug 151 may include a conductive material such as metal, metal oxide, metal nitride, metal silicide, polysilicon, conductive carbon, or a combination thereof. In an embodiment, the contact plug 151 may include W, Ti, TiN, TiO, TiON, or a combination thereof.

The wiring layer 162 may be disposed on the contact plug 151. The wiring layer 162 may pass through the second insulating layer 160 and the first capping insulating layer 140, and contact the upper surface 151US of the contact plug 151.

The wiring layer 162 includes the first wiring section 162a and the second wiring section 162b. The wiring layer 162 may be composed of two sections that have different widths. A section with a relatively smaller width may be referred to as the first wiring section 162a, and a section with a relatively larger width may be referred to as the second wiring section 162b.

The first wiring section 162a may contact the upper surface 151US of the contact plug 151. In an embodiment, a width W2 of the lower surface of the first wiring section 162a may be substantially the same as a width W1 of the upper surface 151US of the contact plug 151. For example, a difference between the width W1 of the upper surface 151US of the contact plug 151 and the width W2 of the lower surface of the first wiring section 162a may be not greater than 5%, 3%, or 1% of an average value of the widths W1 and W2. In an embodiment, the first wiring section 162a may be a pillar that has a cross-section with a substantially constant width. For example, the lower surface of the first wiring section 162a may be the same surface as the upper surface 151US of the contact plug 151. A side surface 162aSS of the first wiring section 162a may contact the first capping insulating layer 140. In some embodiments, the first capping layer 140 may cover at least a portion (e.g., the side surface 162aSS of the first wiring section 162a) of the wiring layer 162. In an embodiment, the first capping insulating layer 140 may surround the side surface 162aSS of the first wiring section 162a. The upper surface of the first wiring section 162a may be formed on substantially the same plane as the upper surface 140US of the first capping insulating layer 140.

The first wiring section 162a may include a first wiring barrier section 162a1 and a first wiring conductive section 162a2. The first wiring barrier section 162a1 may surround a side surface and a lower surface of the first wiring conductive section 162a2. The lowermost surface of the first wiring barrier section 162a1 may contact the upper surface 151US of the contact plug 151. The lowermost surface of the first wiring barrier section 162a1 may be located closer to the conductive layer 114 (e.g., an upper surface of the conductive layer 114) than the upper surface 140US of the first capping insulating layer 140. For example, a distance from the lowermost surface of the first wiring barrier section 162a1 to the conductive layer 114 may be less than a distance from the upper surface 140US of the first capping insulating layer 140 to the conductive layer 114. The first wiring conductive section 162a2 may be spaced apart from the contact plug 151. For example, the first wiring conductive section 162a2 may be spaced apart from the contact plug 151 by a corresponding (e.g., intervening) portion of the first wiring barrier section 162a1.

The second wiring section 162b may be disposed on the first wiring section 162a. The second wiring section 162b is integrally formed with the first wiring section 162a. In an embodiment, a width W3 of a lower surface 162bLS of the second wiring section 162b may be greater than a width of the upper surface of the first wiring section 162a. In an embodiment, the width of the upper surface of the first wiring section 162a may be substantially the same as the width W2 of the lower surface of the first wiring section 162a. The lower surface 162bLS of the second wiring section 162b may contact the upper surface 140US of the first capping insulating layer 140. The lower surface 162bLS of the second wiring section 162b may be formed on substantially the same plane as the upper surface 140US of the first capping insulating layer 140.

The second wiring section 162b may include a second wiring barrier section 162b1 and a second wiring conductive section 162b2. The second wiring barrier section 162b1 may cover a side surface and a lower surface of the second wiring conductive section 162b2. The second wiring barrier section 162b1 may be integrally formed with the first wiring barrier section 162a1. The second wiring conductive section 162b2 may be integrally formed with the first wiring conductive section 162a2.

The wiring layer 162 may include a conductive material such as metal, metal oxide, metal nitride, metal silicide, polysilicon, conductive carbon, or a combination thereof. In an embodiment, the wiring layer 162 may include Cu, Ta, TaN, TaO, TaON, or a combination thereof.

Referring to FIG. 4, a memory device according to embodiments of the present disclosure may further include a second capping insulating layer 152. The second capping insulating layer 152 may be disposed between the first capping insulating layer 140 and the second insulating layer 160. The second capping insulating layer 152 may be disposed on the side surface of the second wiring section 162b. The second capping insulating layer 152 may contact the side surface of the second wiring section 162b. In an embodiment, the second capping insulating layer 152 may include the same material as the first capping insulating layer 140. For example, the second capping insulating layer 152 may include silicon nitride.

The wiring layer 162 includes the first wiring section 162a and the second wiring section 162b. The first wiring section 162a may contact the upper surface 151US of the contact plug 151. In an embodiment, the width W2 of the lower surface of the first wiring section 162a may be substantially the same as the width W1 of the upper surface 151US of the contact plug 151. In an embodiment, the upper surface of the first wiring section 162a may be located closer to the conductive layer 114 (e.g., an upper surface of the conductive layer 114) than the upper surface 140US of the first capping insulating layer 140. For example, a distance from the upper surface of the first wiring section 162a to the conductive layer 114 may be less than a distance from the upper surface 140US of the first capping insulating layer 140 to the conductive layer 114.

The first wiring section 162a may include the first wiring barrier section 162a1 and the first wiring conductive section 162a2. The first wiring barrier section 162a1 and the first wiring conductive section 162a2 may be located between the upper surface 140US of the first capping insulating layer 140 and the upper surface 130US of the first insulating layer 130. For example, the uppermost surface of the first wiring barrier section 162a1 may be located closer to the conductive layer 114 (e.g., an upper surface of the conductive layer 114) than the upper surface 140US of the first capping insulating layer 140. For example, a distance from the uppermost surface of the first wiring barrier section 162a1 to the conductive layer 114 may be less than a distance from the upper surface 140US of the first capping insulating layer 140 to the conductive layer 114.

The second wiring section 162b is integrally formed with the first wiring section 162a. In an embodiment, the width W3 of the lower surface 162bLS of the second wiring section 162b may be greater than the width of the upper surface of the first wiring section 162a. In an embodiment, the width of the upper surface of the first wiring section 162a may be substantially the same as the width W2 of the lower surface of the first wiring section 162a. In an embodiment, the lower surface 162bLS of the second wiring section 162b may be located closer to the conductive layer 114 (e.g., an upper surface of the conductive layer 114) than the upper surface 140US of the first capping insulating layer 140. For example, a distance from the lower surface 162bLS of the second wiring section 162b to the conductive layer 114 may be less than a distance from the upper surface 140US of the first capping insulating layer 140 to the conductive layer 114.

The lower surface 162bLS of the second wiring section 162b may be located between the upper surface 140US of the first capping insulating layer 140 and the upper surface 151US of the contact plug 151.

The second wiring section 162b may include the second wiring barrier section 162b1 and the second wiring conductive section 162b2. At least portions of the second wiring barrier section 162b1 and the second wiring conductive section 162b2 may be located closer to the conductive layer 114 than the upper surface 140US of the first capping insulating layer 140. For example, the lowermost surface of the second wiring barrier section 162b1 may be located closer to the conductive layer 114 (e.g., an upper surface of the conductive layer 114) than the upper surface 140US of the first capping insulating layer 140. For example, a distance from the lowermost surface of the second wiring barrier section 162b1 to the conductive layer 114 may be less than a distance from the upper surface 140US of the first capping insulating layer 140 to the conductive layer 114.

In an embodiment, the first capping insulating layer 140 may cover at least a portion of the wiring layer 162. In an embodiment, the first capping insulating layer 140 may cover at least a portion of the side surface of the second wiring section 162b. The first capping insulating layer 140 may contact the side surface and lower surface 162bLS of the second wiring section 162b.

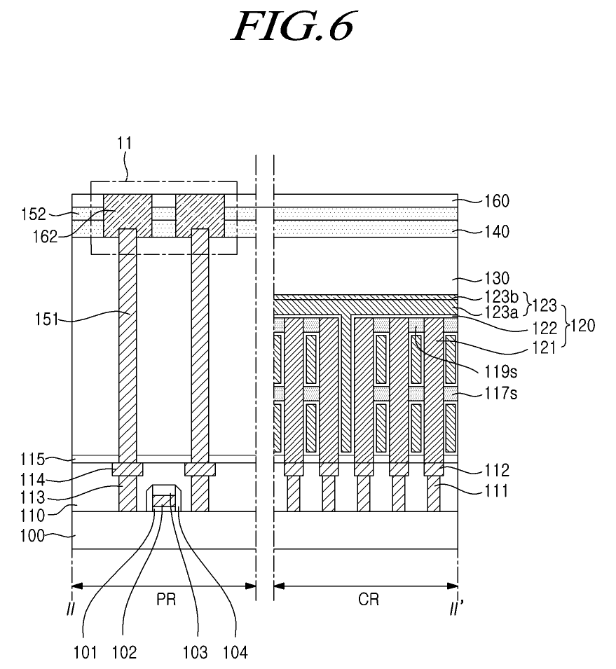

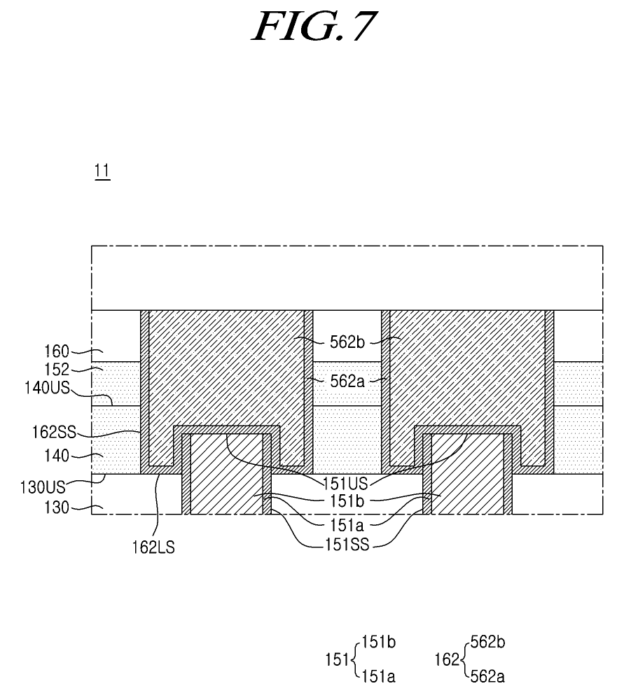

FIG. 5 is a view illustrating a planar structure of a memory device according to embodiments of the present disclosure. FIG. 6 is a view illustrating a cross-sectional structure of a part indicated by a line II-II' of FIG. 5. FIG. 7 is an enlarged view of a part 11 of FIG. 6 according to embodiments of the present disclosure.

Referring to FIG. 5 to FIG. 7, the memory device may include a substrate 100, a gate insulating layer 101, a gate electrode 102, a gate capping layer 103, a spacer 104, an interlayer insulating layer 110, a storage node contact 111, a landing pad 112, a first contact 113, a conductive layer 114, an etch stop layer 115, a capacitor 120, a first support 117s, a second support 119s, a first insulating layer 130, a first capping insulating layer 140, a contact plug 151, a second capping insulating layer 152, a second insulating layer 160, and a wiring layer 162. The capacitor 120 includes a lower electrode 121, a dielectric layer 122, and an upper electrode 123.

The wiring layer 162 may pass through the second insulating layer 160, the second capping insulating layer 152, and the first capping insulating layer 140 and contact an upper surface 151US of the contact plug 151. The wiring layer 162 may include a wiring barrier section 562a and a wiring conductive section 562b. In an embodiment, a distance from the upper surface 151US of the contact plug 151 to the conductive layer 114 (e.g., an upper surface of the conductive layer 114) may be less than a distance from the upper surface 140US of the first capping insulating layer 140 to the conductive layer 114.

In an embodiment, the wiring layer 162 may surround a portion (e.g., an upper portion of a side surface 151SS) of the contact plug 151. The wiring layer 162 may contact the side surface 151SS of the contact plug 151. A lowermost surface 162LS of the wiring layer 162 may be located closer to the conductive layer 114 (e.g., an upper surface of the conductive layer 114) than the upper surface 151US of the contact plug 151. For example, a distance from the lowermost surface 162LS of the wiring layer 162 to the conductive layer 114 may be less than a distance from the upper surface 151US of the contact plug 151 to the conductive layer 114. In an embodiment, the lowermost surface 162LS of the wiring layer 162 may be formed on substantially the same plane as an upper surface 130US of the first insulating layer 130.

In an embodiment, the first capping insulating layer 140 may be spaced apart from the contact plug 151. The first capping insulating layer 140 might not contact the side surface 151SS of the contact plug 151. At least a portion of the wiring layer 162 may fill the space between the first capping insulating layer 140 and the side surface 151SS of the contact plug 151.

In an embodiment, because the wiring layer 162 may contact the upper surface 151US and the side surface 151SS of the contact plug 151, compared to a case where the wiring layer 162 contacts only the upper surface 151US of the contact plug 151, the contact area between the wiring layer 162 and the contact plug 151 may be increased. Therefore, the contact resistance between the wiring layer 162 and the contact plug 151 may be reduced.

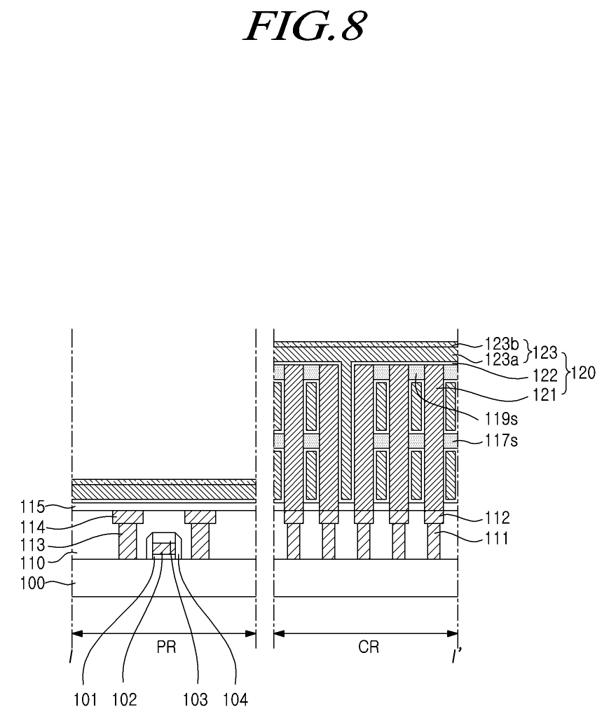

FIG. 8 to FIG. 15 are views illustrating a method of manufacturing a memory device according to embodiments of the present disclosure.

Referring to FIG. 8, an interlayer insulating layer 110 is formed on a substrate 100. Although not illustrated, word lines may be formed by being buried in the substrate 100. A storage node contact 111 and a landing pad 112 are formed in the interlayer insulating layer 110 in a cell region CR. The storage node contact 111 may penetrate the interlayer insulating layer 110 and contact the upper surface of the substrate 100. Although not illustrated, bit lines may be formed between storage node contacts 111. In a peripheral region PR, a first contact 113 and a conductive layer 114 are formed in the interlayer insulating layer 110. The first contact 113 may pass through the interlayer insulating layer 110 and contact the upper surface of the substrate 100.

An etch stop layer 115 is formed on the interlayer insulating layer 110, the landing pad 112 and the conductive layer 114. In an embodiment, the etch stop layer 115 may protect the substrate 100 and various elements formed on the substrate 100 from an etchant during a subsequent wet etching process.

A lower electrode 121, a first support 117s, a second support 119s, a dielectric layer 122 and an upper electrode 123 may be sequentially formed on the etch stop layer 115. The dielectric layer 122 may be formed also on the etch stop layer 115 formed in the peripheral region PR. The dielectric layer 122 may be formed on the surfaces of the first support 117s, the second support 119s, the lower electrode 121, and the etch stop layer 115 formed in the cell region CR. The upper electrode 123 may include a first upper electrode 123a and a second upper electrode 123b. The first upper electrode 123a may fill the regions between lower electrodes 121. The etch stop layer 115 may include a material different from a first insulating layer 130. In an embodiment, the etch stop layer 115 exhibits different etching characteristics from the first insulating layer 130, and thus, may provide an etch stop function.

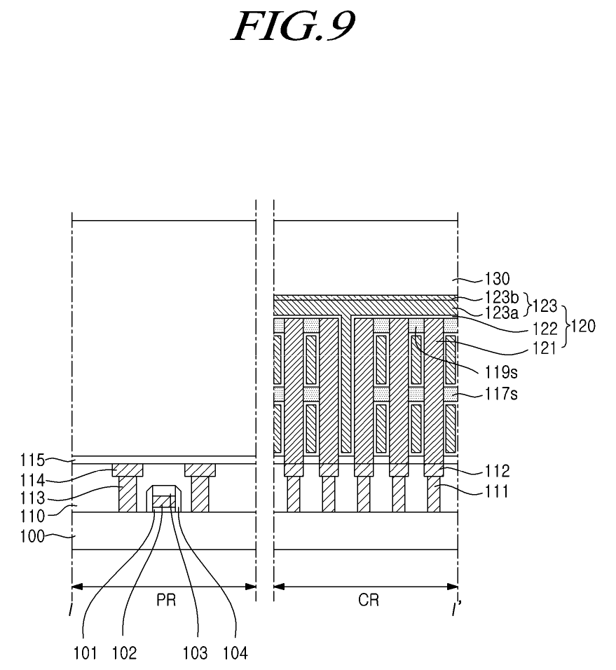

Referring to FIG. 9, portions of the dielectric layer 122 and the upper electrode 123 may be removed. In an embodiment, portions of the dielectric layer 122 and the upper electrode 123 that are located in the peripheral region PR may be removed.

The first insulating layer 130 may be formed on the etch stop layer 115 and the upper electrode 123. The first insulating layer 130 may cover the upper surfaces of the etch stop layer 115 and the upper electrode 123.

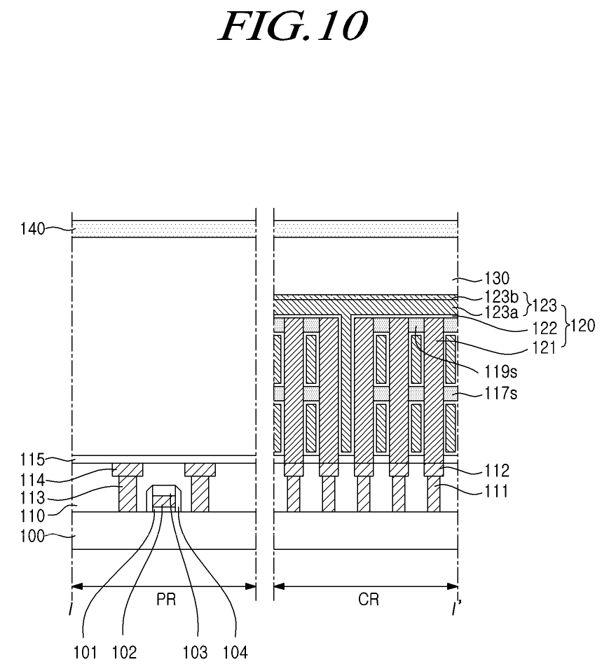

Referring to FIG. 10, a first capping insulating layer 140 may be formed on the first insulating layer 130. The first capping insulating layer 140 may include a material different from a material that forms the first insulating layer 130. In an embodiment, the first capping insulating layer 140 may include nitride.

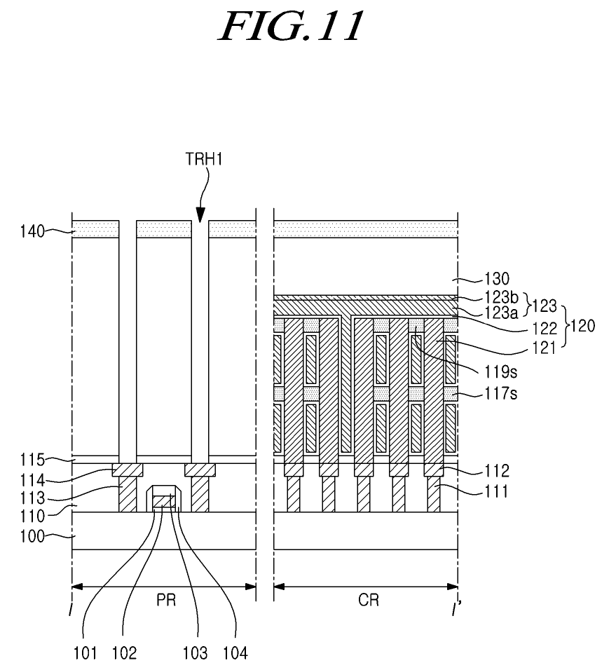

Referring to FIG. 11, a first through hole TRH1 that penetrates the first insulating layer 130 and the first capping insulating layer 140 may be formed. The first through hole TRH1 may be formed in the peripheral region PR. The first through hole TRH1 may penetrate the first capping insulating layer 140, the first insulating layer 130, and the etch stop layer 115 to expose the upper surface of the conductive layer 114.

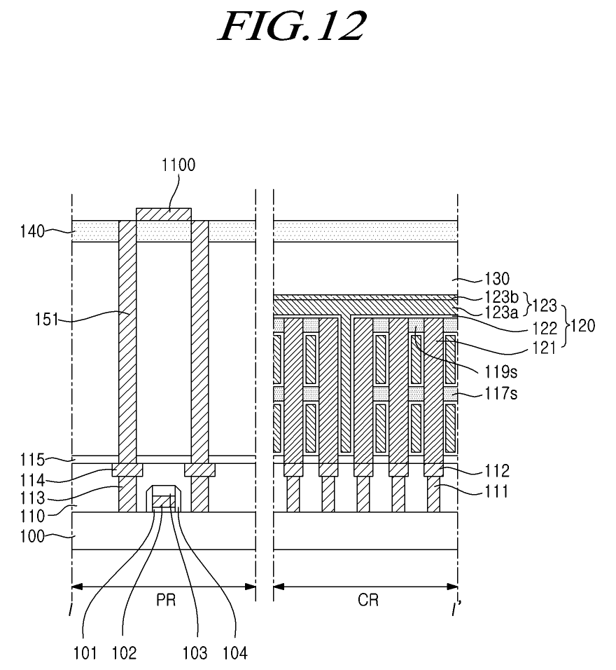

Referring to FIG. 12, a contact plug 151 may be formed in the first through hole TRH1. A process of forming the contact plug 151 may include a process of depositing a conductive material and then removing at least a portion of the deposited conductive material. In an embodiment, the process of removing at least a portion of the conductive material may include an etch back process, a chemical mechanical polishing (CMP) process, or a combination thereof.

When performing the process of removing at least a portion of the conductive material, a residue 1100 of the conductive material may remain on the first capping insulating layer 140. The residue 1100 may be located between neighboring contact plugs 151. For example, the residue 1100 may exist even when the upper surface of the contact plug 151 be formed on substantially the same plane as the upper surface of the first capping insulating layer 140.

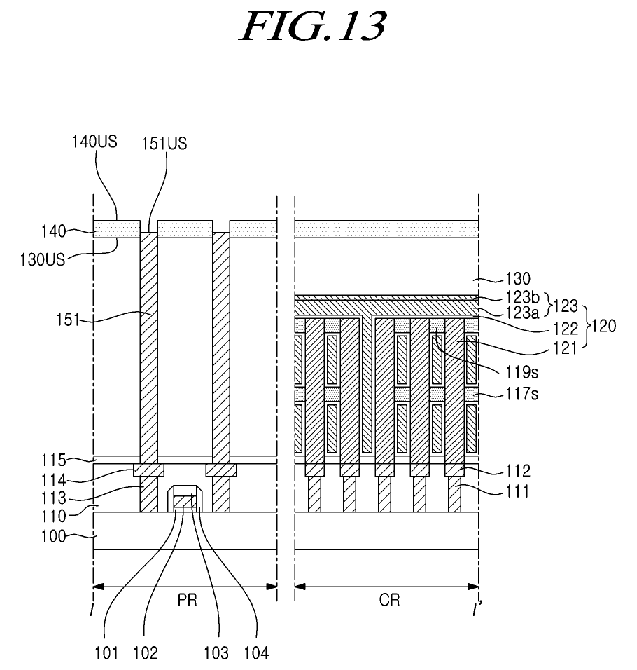

Referring to FIG. 13, at least a portion (e.g., an upper portion) of the contact plug 151 may be further removed. When the at least a portion of the contact plug 151 is removed, the residue 1100 may be removed together. In an embodiment, a process of removing the at least a portion of the contact plug 151 may include an etching process.

As the at least a portion of the contact plug 151 is removed, an upper surface 151US of the contact plug 151 may be located closer to the conductive layer 114 than an upper surface 140US of the first capping insulating layer 140. For example, a distance from the upper surface 151US of the contact plug 151 to the conductive layer 114 (e.g., an upper surface of the conductive layer 114) may be less than a distance from the upper surface 140US of the first capping insulating layer 140 to the conductive layer 114. In an embodiment, the upper surface 151US of the contact plug 151 may be located between the upper surface 140US of the first capping insulating layer 140 and an upper surface 130US of the first insulating layer 130. In an embodiment, when removing the at least a portion of the contact plug 151, the time and/or intensity of the etching process may be adjusted so that the upper surface 151US of the contact plug 151 does not go below the upper surface 130US of the first insulating layer 130. For example, with a given etch rate, a portion of the contact plug 151 may be removed during a time interval sufficiently long to ensure that the residue 1100 on the first capping insulating layer 140 is substantially entirely removed together and sufficiently short to keep the upper surface 151US of the removed contact plug 151 at a level higher than the upper surface 130US of the first insulating layer 130.

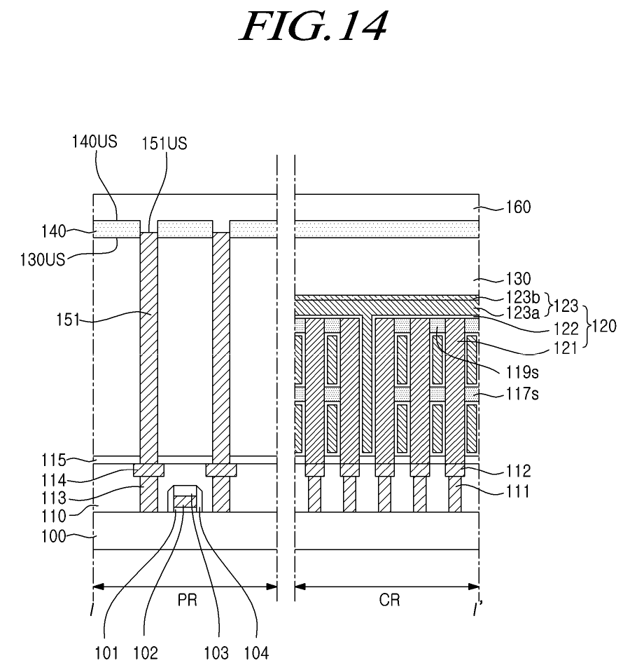

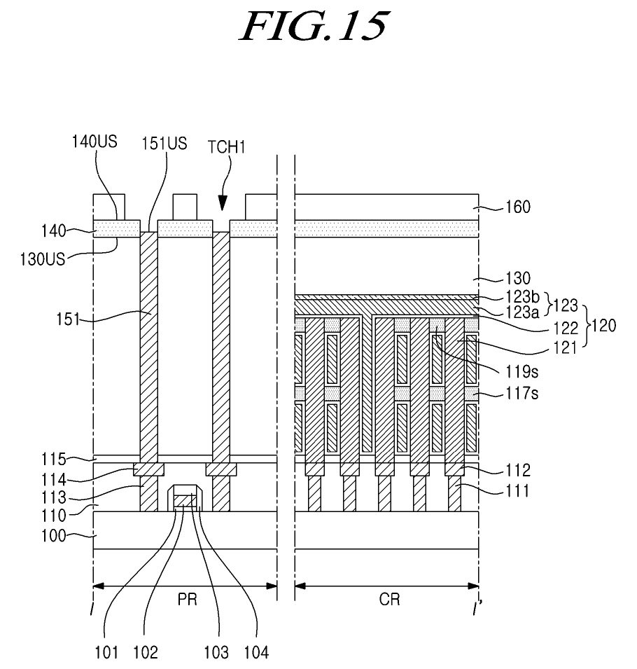

Referring to FIG. 14, a second insulating layer 160 may be formed on the first capping insulating layer 140 and the contact plug 151. The second insulating layer 160 may fill the space formed due to removal of the at least a portion of the contact plug 151. In an embodiment, the second insulating layer 160 may include oxide and nitride.

Referring to FIG. 15, as at least a portion of the second insulating layer 160 is removed in the peripheral region PR, a first trench TCH1 may be formed. The first trench TCH1 may overlap the contact plug 151. The first trench TCH1 may be formed to correspond to each contact plug 151. In an embodiment, the width of the first trench TCH1 may be greater than the width of the contact plug 151. As the first trench TCH1 is formed, the upper surface 151US of the contact plug 151 may be exposed again. For example, the first trench TCH1 may include a first portion (e.g., a lower portion) and a second portion (e.g., an upper portion), where the first portion has a width that is substantially the same as a width of the contact plug 151 and the second portion has a width greater than the width of the first portion. A process of forming the first trench TCH1 may include an etching process.

In an embodiment, when the first trench TCH1 is formed, the first capping insulating layer 140 might not be substantially removed. In an embodiment, the process of forming the first trench TCH1 may include a process of selectively removing only the second insulating layer 160.

Referring again to FIG. 2, a wiring layer 162 may be formed in the first trench TCH1. In an embodiment, a process of forming the wiring layer 162 may include a damascene process. In an embodiment, the wiring layer 162 may include Cu, Ta, TaN, TaO, TaON, or a combination thereof. The wiring layer 162 may contact the upper surface 151US of the contact plug 151. The first capping insulating layer 140 may cover at least a portion of the wiring layer 162. For example, the first capping insulating layer 140 may surround a portion of the side surface of the wiring layer 162.

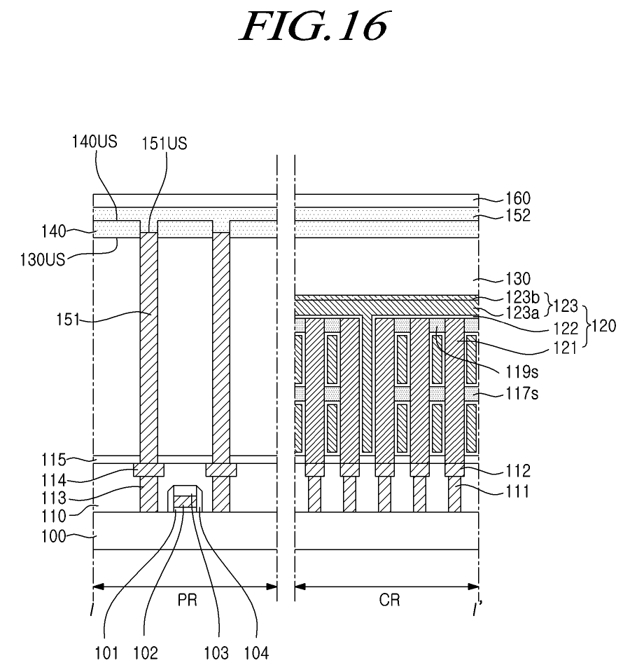

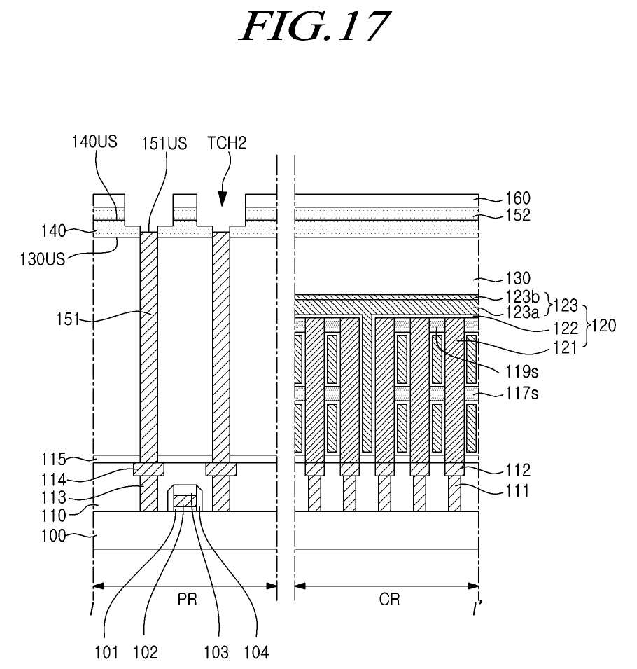

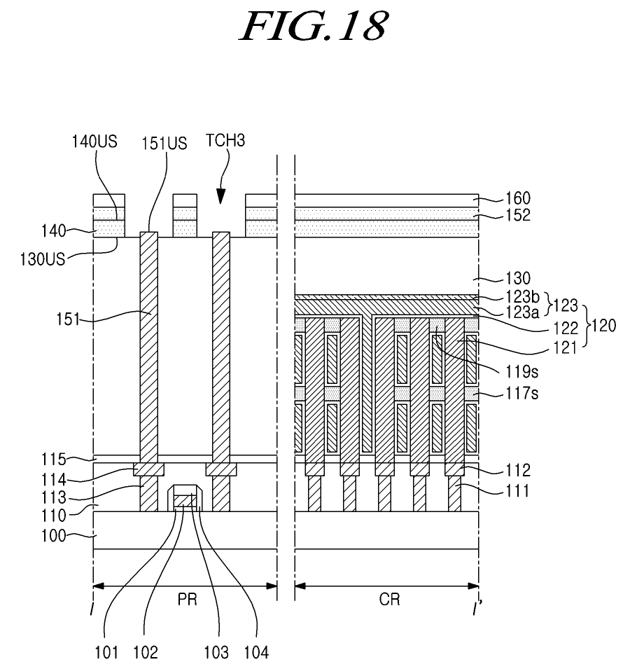

FIGS. 16 and 17 are views illustrating a method of manufacturing a memory device according to embodiments of the present disclosure.

The memory device illustrated in FIG. 16 may be formed by substantially the same method as the method of manufacturing a memory device described above with reference to FIG. 8 to FIG. 13.

Referring to FIG. 16, a second capping insulating layer 152 may be formed on the first capping insulating layer 140 and the contact plug 151. The second capping insulating layer 152 may fill the space formed due to removal of the at least a portion of the contact plug 151. The second capping insulating layer 152 may include the same material as the first capping insulating layer 140. In an embodiment, the second capping insulating layer 152 may include nitride.

A second insulating layer 160 may be formed on the second capping insulating layer 152. The second insulating layer 160 may include a material different from a material that forms the second capping insulating layer 152. In an embodiment, the second insulating layer 160 may include oxide.

Referring to FIG. 17, in the peripheral region PR, at least portions of the second insulating layer 160, the second capping insulating layer 152, and the first capping insulating layer 140 may be removed to form a second trench TCH2. The second trench TCH2 may overlap the contact plug 151. The second trench TCH2 may be formed to correspond to each contact plug 151. In an embodiment, the width of the second trench TCH2 may be larger than the width of the contact plug 151. As the second trench TCH2 is formed, the upper surface 151US of the contact plug 151 may be exposed again. For example, the second trench TCH2 may include a first portion (e.g., a lower portion) and a second portion (e.g., an upper portion), where the first portion has a width that is substantially the same as a width of the contact plug 151 and the second portion has a width greater than the width of the lower portion. A process of forming the second trench TCH2 may include an etching process.

In an embodiment, the process of forming the second trench TCH2 may include a process of removing the second insulating layer 160 and a process of removing the second capping insulating layer 152. The process of removing the second capping insulating layer 152 may be performed separately from the process of removing the second insulating layer 160. For example, the process of removing the second capping insulating layer 152 may be performed after the process of removing the second insulating layer 160 is performed.

In an embodiment, when the second capping insulating layer 152 is removed, at least a portion of the first capping insulating layer 140 may be removed together. In an embodiment, the bottom surface of the upper portion of the second trench TCH2 may be located farther from the conductive layer 114 than the upper surface 151US of the contact plug 151. In an embodiment, the bottom surface of the upper portion of the second trench TCH2 may be located between the upper surface 140US of the first capping insulating layer 140 and the upper surface 130US of the first insulating layer 130.

Referring again to FIG. 4, a wiring layer 162 may be formed in the second trench TCH2. In an embodiment, a process of forming the wiring layer 162 may include a damascene process. The wiring layer 162 may include a first wiring section 162a that contacts the upper surface 151US of the contact plug 151 and a second wiring section 162b that is integrally formed with the first wiring section 162a and includes a lower surface with a width greater than the upper surface of the first wiring section 162a. The first capping insulating layer 140 may cover at least a portion of the wiring layer 162. For example, the first capping insulating layer 140 may surround a side surface 162aSS of the first wiring section 162a and a portion of a side surface of the second wiring section 162b. In an embodiment, a lower surface 162bLS of the second wiring section 162b may be located between the upper surface 140US of the first capping insulating layer 140 and the upper surface 130US of the first insulating layer 130.

FIG. 18 illustrates a method of manufacturing a memory device according to embodiments of the present disclosure. The memory device illustrated in FIG. 18 may be formed by substantially the same method as the method of manufacturing a memory device described above with reference to FIG. 8 to FIG. 13 and FIG. 16.

Referring to FIG. 18, in the peripheral region PR, at least portions of the second insulating layer 160, the second capping insulating layer 152, and the first capping insulating layer 140 may be removed to form a third trench TCH3. The third trench TCH3 may overlap the contact plug 151. The third trench TCH3 may be formed to correspond to each contact plug 151. In an embodiment, the width of the third trench TCH3 may be larger than the width of the contact plug 151. As the third trench TCH3 is formed, the upper surface 151US of the contact plug 151 and the upper surface 130US of the first insulating layer 130 may be exposed again. A process of forming the third trench TCH3 may include an etching process.

In an embodiment, the process of forming the third trench TCH3 may include a process of removing the second insulating layer 160 and a process of removing the second capping insulating layer 152. The process of removing the second capping insulating layer 152 may be performed separately from the process of removing the second insulating layer 160. For example, the process of removing the second capping insulating layer 152 may be performed after the process of removing the second insulating layer 160 is performed.

In an embodiment, when the second capping insulating layer 152 is removed, at least a portion of the first capping insulating layer 140 may be removed together. For example, when the second capping insulating layer 152 is removed, a portion of the first capping insulating layer 140 may be removed to expose the upper surface 130US of the first insulating layer 130. In an embodiment, the bottom surface (or a lowermost surface) of the third trench TCH3 may be located closer to the conductive layer 114 (e.g., an upper surface of the conductive layer 114) than the upper surface 151US of the contact plug 151. For example, a distance from the bottom surface of the third trench TCH3 to the conductive layer 114 may be less than a distance from the upper surface 151US of the contact plug 151 to the conductive layer 114. In an embodiment, the bottom surface of the third trench TCH3 may be formed on substantially the same plane as the upper surface 130US of the first insulating layer 130.

Referring again to FIG. 6 and FIG. 7, a wiring layer 162 may be formed in the third trench TCH3. In an embodiment, a process of forming the wiring layer 162 may include a damascene process. In an embodiment, the first capping insulating layer 140 may cover at least a portion of the wiring layer 162. For example, the first capping insulating layer 140 may surround a portion of a side surface 162SS of the wiring layer 162. The first capping insulating layer 140 may be spaced apart from the contact plug 151. A lowermost surface 162LS of the wiring layer 162 may be located closer to the conductive layer 114 than the upper surface 151US of the contact plug 151. The wiring layer 162 may surround a portion (e.g., an upper portion of a side surface 151SS) of the contact plug 151.

Referring again to FIG. 2 and FIG. 3, the memory device according to the embodiments of the present disclosure may include the contact plug 151 and the wiring layer 162 which is connected to the contact plug 151. The upper surface 151US of the contact plug 151 may be located between the upper surface 140US of the first capping insulating layer 140 and the upper surface 130US of the first insulating layer 130.

As described above with reference to FIG. 13, the residue 1100 that remains between neighboring contact plugs 151 when forming the contact plugs 151 may be removed. When the residue 1100 is removed, at least a portion (e.g., the upper portion) of the contact plug 151 may be removed together. As the upper portion of the contact plug 151 is removed together, a phenomenon in which contact plugs 151 or portions of the wiring layer 162 are short-circuited due to the presence of the residue 1100 may be substantially prevented in a memory device according to embodiments of the present disclosure.

The above description has been presented to enable any person skilled in the art to make, use, and practice the technical features of the present disclosure, and has been provided in the context of a particular application and its requirements as examples. Various modifications, additions and substitutions to the described embodiments may be possible.

What is claimed is:

1. A memory device comprising:
a substrate including a cell region and a peripheral region;
a conductive layer disposed over the substrate, and located in the peripheral region;
a first capping insulating layer over the conductive layer;
a contact plug contacting an upper surface of the conductive layer, a distance from an upper surface of the contact plug to the conductive layer being less than a distance from an upper surface of the first capping insulating layer to the conductive layer; and
a wiring layer contacting the upper surface of the contact plug.

2. The memory device according to claim 1, wherein the first capping insulating layer covers at least a portion of the wiring layer.

3. The memory device according to claim 1, further comprising a first insulating layer over the conductive layer,
wherein the upper surface of the contact plug is farther from the conductive layer than an upper surface of the first insulating layer.

4. The memory device according to claim 1, wherein the wiring layer includes a first wiring section and a second wiring section, the first wiring section contacts the upper surface of the contact plug and includes a lower surface having substantially the same width as the upper surface of the contact plug, and the second wiring section is integrally formed with the first wiring section and includes a lower surface having a width greater than an upper surface of the first wiring section.

5. The memory device according to claim 4, wherein the first capping insulating layer surrounds a side surface of the first wiring section.

6. The memory device according to claim 4, wherein the lower surface of the second wiring section contacts the upper surface of the first capping insulating layer.

7. The memory device according to claim 4, wherein a distance from the lower surface of the second wiring section to the conductive layer is less than a distance from the upper surface of the first capping insulating layer to the conductive layer.

8. The memory device according to claim 1, further comprising a second capping insulating layer disposed on the first capping insulating layer,
wherein the second capping insulating layer is located on a side surface of the wiring layer, and includes the same material as the first capping insulating layer.

9. The memory device according to claim 1, wherein the wiring layer surrounds a portion of the contact plug.

10. The memory device according to claim 9, wherein a distance from a lowermost surface of the wiring layer to the conductive layer is less than a distance from the upper surface of the contact plug to the conductive layer.

11. A memory device comprising:
a substrate including a cell region and a peripheral region;
a conductive layer disposed over the substrate, and located in the peripheral region;
a contact plug contacting an upper surface of the conductive layer; and
a wiring layer including a first wiring section and a second wiring section, the first wiring section contacting an upper surface of the contact plug and including a lower surface that has substantially the same width as the upper surface of the contact plug, the second wiring section being integrally formed with the first wiring section and including a lower surface that has a width greater than an upper surface of the first wiring section.

12. The memory device according to claim 11, further comprising a first capping insulating layer over the conductive layer,
wherein a distance from the upper surface of the contact plug to the conductive layer is less than a distance from an upper surface of the first capping insulating layer to the conductive layer.

13. The memory device according to claim 12, wherein the first capping insulating layer surrounds a side surface of the first wiring section.

14. The memory device according to claim 12, wherein the lower surface of the second wiring section contacts the upper surface of the first capping insulating layer.

15. The memory device according to claim 12, wherein a distance from the lower surface of the second wiring section to the conductive layer is less than a distance from the upper surface of the first capping insulating layer to the conductive layer.

16. The memory device according to claim 11, wherein the first wiring section includes a first wiring conductive section and a first wiring barrier section, the first wiring barrier section surrounding a side surface and a lower surface of the first wiring conductive section, and
wherein a lowermost surface of the first wiring barrier section contacts the upper surface of the contact plug.

17. The memory device according to claim 16, wherein the first wiring conductive section is spaced apart from the contact plug.

18. A memory device comprising:
a substrate;
a conductive layer over the substrate;
a first insulating layer on the conductive layer;
a first capping insulating layer on the first insulating layer;
a contact plug contacting an upper surface of the conductive layer, passing through the first insulating layer, and including an upper surface that is located between an upper surface of the first capping insulating layer and an upper surface of the first insulating layer; and
a wiring layer including a first wiring section and a second wiring section, the first wiring section contacting the upper surface of the contact plug and including a lower surface having substantially the same width as the upper surface of the contact plug, the second wiring section being integrally formed with the first wiring section and including a lower surface that has a width greater than an upper surface of the first wiring section.

19. The memory device according to claim 18, wherein the first capping insulating layer surrounds a side surface of the first wiring section.

20. The memory device according to claim 18, wherein the first insulating layer includes oxide, and the first capping insulating layer includes nitride.
